(19) United States
(12) Patent Application Publication
(10) Pub. No.: US 2025/0318227 A1
(43) Pub. Date: Oct. 9, 2025

(54) SEMICONDUCTOR STRUCTURE AND SEMICONDUCTOR DEVICE

(71) Applicant: SUZHOU WATECH ELECTRONICS CO., LTD., Suzhou (CN)

(72) Inventors: Dancheng YUE, Suzhou (CN); Yaohui ZHANG, Suzhou (CN); Yu LIU, Suzhou (CN); Changchang WANG, Suzhou (CN); Xiaoyu ZHANG, Suzhou (CN)

(73) Assignee: SUZHOU WATECH ELECTRONICS CO., LTD., Suzhou (CN)

(21) Appl. No.: 19/098,968

(22) Filed: Apr. 2, 2025

(30) Foreign Application Priority Data
Apr. 3, 2024 (CN) 202410404497.7

(51) Int. Cl. H10D 62/60; H10D 30/00; H10D 30/62; H10D 62/10; H10D 84/85; H10D 86/00

(52) U.S. Cl. CPC H10D 62/60; H10D 30/502; H10D 30/62; H10D 62/102; H10D 84/853; H10D 86/201

(57) ABSTRACT

A semiconductor structure includes a gate structure region; a source region and a drain region disposed on two sides of the gate structure respectively. The gate structure region includes a channel region and a gate region disposed from inside to outside. The channel region is surrounded inside an inner cavity of the gate region and attached to the source region, the drain region, and the gate region, and an ion doping type of the drain region, an ion doping type of the source region and an ion doping type of the channel region are same.

### CROSS-REFERENCE TO RELATED APPLICATIONS

This application claims priority to Chinese Patent Application No. 202410404497.7, filed on Apr. 3, 2024, the content of which is incorporated herein by reference in its entirety.

### TECHNICAL FIELD

The present disclosure relates to the technical field of semiconductors, and more particularly to a semiconductor structure and a semiconductor device.

### BACKGROUND

With the rapid development of semiconductor technology, as a modern electronic information industry, the complementary metal-oxide-semiconductor (CMOS) integrated circuits scale is increasing. The main reason is the continual reduction of the characteristic size of the CMOS device, and the most advanced 5 nm semiconductor process has been in mass production. However, with the continuous improvement in integration, the continuous increase in power consumption of an integrated circuit chip has become a difficult problem for the development of integrated circuits.

The short channel effect (SCE) is an important factor besides the higher requirements for manufacturing process accuracy. The short channel effects are effects that occur in the transistor in a case where the conducted channel length of the metal oxide semiconductor field effect transistor is reduced to the order of tens of nanometers or even a few nanometers. The short channel effect mainly includes threshold voltage decreasing with the channel length, drain-induced barrier lowering, carrier surface scattering, velocity saturation effect, and so on. The existence of the short channel effect makes the characteristic size of the semiconductor device can not be further reduced. To reduce the short channel effect, currently, the industry has adopted special device structures, for example, under the 14 nm node, a fin field-effect transistor (FinFEF) and an all-envelop gate field-effect transistor are provided, under the 5 nm node, a gate-all-around transistor (GAA) device is provided to improve the impact of the short channel effect on the device. Currently, the GAA device is applied more widely, while the PN junction is still in the GAA device, that is, problems such as doping diffusion remain, which limits the size of the device. Moreover, as a surface channel device, the GAA device has problems such as surface mobility and the hot carrier effect.

Therefore, a semiconductor device that can further break through the characteristic size is urgently needed.

### SUMMARY

To solve the above-described problems, a semiconductor structure and a semiconductor device are provided by the embodiment of the present disclosure.

The first aspect of the embodiment of the present disclosure provides a semiconductor structure at least comprising:
a gate structure region; and
a source region and a drain region disposed on two sides of the gate structure respectively; where the gate structure region at least comprises:
a channel region and a gate region disposed from inside to outside; where the channel region is surrounded by the inner cavity of the gate region and attached to the source region, the drain region, and the gate region, an ion doping type of the drain region, an ion doping type of the source region and an ion doping type of the channel region are the same.

In an alternative embodiment of the present disclosure, the gate structure region further comprises:
a dielectric layer disposed between the gate region and the channel region, and attached to the gate region, the channel region, the drain region, and the source region.

In an alternative embodiment of the present disclosure, the gate structure region further comprises:
a buffer isolation region disposed between the channel region and the dielectric layer, and attached to the dielectric layer, the channel region, the drain region, and the source region.

In an alternative embodiment of the present disclosure, an ion doping concentration of the buffer isolation region is not larger than 1e17/cm³.

In an alternative embodiment of the present disclosure, the ion doping concentration of the buffer isolation region is less than an ion doping concentration of the drain region and an ion doping concentration of the source region; and/or, the ion doping concentration of the buffer isolation region is one order of magnitude less than the ion doping concentration of the channel region.

In an alternative embodiment of the present disclosure, a thickness of the buffer isolation region ranges from 0.3 nm to 5 nm.

In an alternative embodiment of the present disclosure, an ion doping concentration of the gate region ranges from 1e16/cm³ to 1e20/cm³; and/or, the ion doping concentration of the channel region ranges from 1e17/cm³ to 5e19/cm³; and/or, the ion doping concentration of the drain region and the ion doping concentration of the source region range from 1e18/cm³ to 5e20/cm³.

In an alternative embodiment of the present disclosure, the ion doping concentration of the drain region, the ion doping concentration of the source region, and the ion doping concentration of the channel region are equal.

In an alternative embodiment of the present disclosure, the ion doping concentration of the drain region, the ion doping concentration of the source region, and the ion doping concentration of the channel region are not less than 1e17/cm³.

In an alternative embodiment of the present disclosure, the drain region, the source region, and the channel region are made integrally.

In an alternative embodiment of the present disclosure, the semiconductor structure is an N-type device and the gate region is a metal having a metal working function ranging from 4.5 eV to 5.2 eV; or
the semiconductor structure is a P-type device and the gate region is a metal having a metal working function ranging from 4.0 eV to 4.5 eV.

In an alternative embodiment of the present disclosure, the semiconductor structure is a FinFET device or a GAA device.

The second aspect of the embodiment of the present disclosure provides a semiconductor device comprising:
any one of the semiconductor structures as described above.

In an alternative embodiment of the present disclosure, the number of the semiconductor structures is a plurality, and the conduction type of the plurality of the semiconductor structures is not identical.

In an alternative embodiment of the present disclosure, a first semiconductor structure and a second semiconductor structure are stacked along the vertical direction on a surface of the substrate layer, the first semiconductor structure comprises a plurality of semiconductor structures of a first conduction type, the second semiconductor structure comprises a plurality of semiconductor structures of a second conduction type, and the first conduction type is different from the second conduction type.

In an alternative embodiment of the present disclosure, the semiconductor device as described above further comprises:
an insulating layer, disposed between the first semiconductor structure and the second semiconductor structure, and through the semiconductor gate region.

In the first aspect, the drain region, the source region, and the channel region of the embodiment of the present disclosure are all doped with the same type of ions, are homojunction device structures, and have no interface effect between regions. By converting conventional interface conduction to body conduction, the drift velocity of the electrons or the drift velocity of holes is higher and the mobility efficiency of the carrier is higher, resulting in a higher drift velocity of the electrons or a higher drift velocity of holes and further improving the working efficiency and the device reliability of the semiconductor structure.

In the second aspect, the drain region, the source region, and the channel region in the embodiment of the present disclosure are all doped with the same type of ions, the conventional interface conduction is converted into the body conduction, and the channel region is directly controlled by the gate electrode.

In a case where no voltage or 0 V voltage applied to the gate region, due to the energy band difference between the gate region and the channel region (the electron affinity of the Si device (the difference between the bottom of the conduction band to the vacuum energy level) is 4.05 eV), the channel region of the device is self-depleted by the affecting of the gate region to form a self-depleted non-inverted semiconductor structure. That is, only in the case where a voltage is applied to the gate region, does the current flow from the high doping region of the drain region through the channel region to the source region, that is the channel region is turned on. In the case where no voltage is applied to the gate region, the channel region is in an off state, forming a normally-off device and consuming less energy than the conventional normally-on device.

In the third aspect, the semiconductor structure provided by the embodiment of the present disclosure is body conduction, and the device has no PN junction structure. The threshold voltage reduction effect caused by the PN junction can be eliminated with no PN junction depletion layer, that is, the characteristic size can be further reduced. Experiments have shown the channel length of the device can meet the requirement of less than 10 nm.

In the fourth aspect, the semiconductor structure provided by the embodiment of the present disclosure is body conduction, the conducting current away from the interface, and no problem of lowering interface mobility. The conducting current is away from the interface further reduces tunneling current and gate leakage, and improves the reliability and stability of the device structure.

In the fifth aspect, the semiconductor structure provided by the embodiment of the present disclosure is a non-inverted type device, the electrons of the channel region do not flow through the surface inversion layer, thus avoiding the gate leakage of the device. At the nanoscale, the tunneling current caused by the tunneling effect is the main source of the gate leakage, the thickness of the gate dielectric of the device is limited, and the high-k dielectric has been developed. After adopting the high-k dielectric, the gate dielectric can be thickened without decreasing the control capability of the gate. The semiconductor structure provided by the embodiment of the present disclosure can reduce tunneling current due to the current not on the surface inversion layer, and cannot adopt the high-k dielectric, providing a new technical direction.

### BRIEF DESCRIPTION OF THE DRAWINGS

The drawings described herein are intended to provide a further understanding of the present disclosure and are incorporated in and constitute a part of this specification, schematic embodiments of the disclosure together with the description serve to explain the principles of the present disclosure, and do not constitute an improper limitation of the present disclosure. In the drawings:

FIG. 1 is a process flow diagram of the conventional GAA;

FIG. 2 is a schematic structure diagram of the semiconductor structure provided by the embodiment of the present disclosure;

FIG. 3 is a schematic simulation structure diagram of the semiconductor structure provided by the embodiment of the present disclosure;

FIG. 4 is a sectional view of the gate structure of the semiconductor structure provided by the embodiment of the present disclosure;

FIG. 5 is a data graph of the semiconductor structure provided by the embodiment of the present disclosure in an on state, illustrating simulation results of the electron concentration of the vertical channel region;

FIG. 6 is an energy band diagram and an electron distribution diagram of the buffer isolation region and the channel region of the case where the semiconductor structure provided by the embodiment of the present disclosure is an N-type device in an off state;

FIG. 7 is a transfer characteristic curve graph and a gate leakage curve graph of the case where the semiconductor structure provided by the embodiment of the present disclosure is an N-type device with a total gate width of 1 mm;

FIG. 8 is a transfer characteristic curve graph for different Vd of the case where the semiconductor structure provided by the embodiment of the present disclosure is an N-type device with a total gate width of 1 mm;

FIG. 9 is an energy band diagram and a hole distribution diagram of the buffer isolation region and the channel region of the case where the semiconductor structure provided by the embodiment of the present disclosure is a P-type device in an off state;

FIG. 10 is a transfer characteristic curve graph and a gate leakage curve graph of the case where the semiconductor structure provided by the embodiment of the present disclosure is a P-type device with a total gate width of 1 mm;

FIG. 11 is a transfer characteristic curve graph for different Vd of the case where the semiconductor structure provided by the embodiment of the present disclosure is a P-type device with a total gate width of 1 mm; and

FIG. 12 is a schematic device diagram of the semiconductor device provided by the embodiment of the present disclosure.

### DETAILED DESCRIPTION OF THE EMBODIMENTS

With the rapid development of semiconductor technology, as a modern electronic information industry, the complementary metal-oxide-semiconductor (CMOS) integrated circuits scale is increasing. The main reason is the continual reduction in the characteristic size of the CMOS device, and the most advanced 5 nm semiconductor process now is in mass production. However, with the continuous increase in integration, the continuous increase in power consumption of an integrated circuit chip has become a difficult problem for the development of integrated circuits.

The short channel effect (SCE) is an important factor besides the higher requirements for process preparation accuracy. The short channel effects are effects that occur in the transistor in a case where the conducted channel length of the metal oxide semiconductor field effect transistor is reduced to the order of tens of nanometers or even a few nanometers. The short channel effects mainly include: the threshold voltage decreases with the channel length, drain-induced barrier lowering, carrier surface scattering, velocity saturation effect, and so on. The existence of the short channel effects makes the characteristic size of the semiconductor device cannot be further reduced. To reduce the short channel effects, currently, the industry has adopted special device structures, for example, a fin field-effect transistor (FinFEF) and an all-envelop gate field-effect transistor are provided under the 14 nm node, a gate-all-around transistor (GAA) device is provided under the 5 nm node, to improve the impact of the short channel effects on the device.

Currently, the GAA device is in a more widely application, while the PN junction is still in the GAA device, that is, the problems such as doping diffusion remain and limit the size of the device. Moreover, as a surface channel device, the GAA device has problems such as surface mobility and the hot carrier effect. For example, the conventional GAA device has the following defects.

### (1) Short Channel Effect and Narrow Channel Effect Affecting the Threshold Voltage

In the case where the channel length is reduced to a certain extent, the proportion of the depletion region of the source and the drain in the whole channel increases, the charges required to form the inversion layer on the silicon surface below the gate decrease, and the threshold voltage decreases. Meanwhile, the threshold voltage increases due to the charges in the widened part of the depletion region along the channel width. When the channel width decreases to the same order as the depletion region width, the threshold voltage decreases significantly, and the threshold voltage of the short channel device is very sensitive to the change of the channel length.

### (2) Mobility Field Correlation Effect and Carrier Velocity Saturation Effect

In a low field, the mobility is constant and the carrier velocity increases linearly with the electric field. In a high field, the mobility field decreases, and the carrier velocity saturates and is no longer related to the electric field. The conventional device has a surface inversion layer in an on state, the electron layer disposed on the interface of the device affected by the interface scattering. Drain saturation current and current characteristics of the device are determined by the interface mobility, and the mobility decreases affected by the surface scattering and Coulomb scattering in the semiconductor surface, and the surface carrier saturation velocity decreases. Meanwhile, the extremely strong electric field in the vertical interface direction of the gate will further reduce the carrier mobility.

### (3) Degradation of Subthreshold Characteristics and the Device Cannot Pinch Off

The subthreshold region leakage makes the off-state characteristics of the MOSFET device worse and the static power consumption larger, resulting in logic state confusion in dynamic circuits and memory cells. The drain-induced barrier lowering (DIBL) effect caused by the short channel is a basic physical effect that determines the size limit of the short channel MOS device. The DIBL effect is in a case where a high voltage is applied to the drain, the source junction barrier lowers because the gate is short and the source is affected by the drain electric field. The drain depletion region extends and even connects to the source junction, making the device cannot pinch off. The drain voltage affects the off of the gate and affects the potential. In a case where the drain voltage increases, the drain voltage will not be affected after the normal turning off. In the case where the short channel effects exist, changing with the drain voltage, the higher the drain voltage, the higher the current.

### (4) Gate Dielectric Layer Tunneling and Gate Leakage of the Device

The tunneling current is the current in microelectronics technology quantum tunneling effects of the carriers occur in a case where the semiconductor barrier or the thickness of the silicon dioxide thin film is as thin as the length of the de Broglie wave in the microelectronics. In a case where the size of the device scales down to the nanoscale, the tunneling current in the gate oxide layer by the tunneling effect cannot be ignored and becomes an important factor affecting the miniature device. In a case where the device is an inversion device, the carriers of the device exist at the interface of the device and the highest at the interface, and the tunneling current of the device is strong.

### (5) 3D Integrated and Annealing Process

The device process requires ion implantation and annealing, and annealing is contradictory to the low-temperature process. Temperature brings two problems, the first is diffusion, where the diffusion of the PN junction makes it impossible to miniature to a small size, and the second is that the high-temperature process cannot be adopted after the metal and the silicide process, damaging the silicide and metal structure.

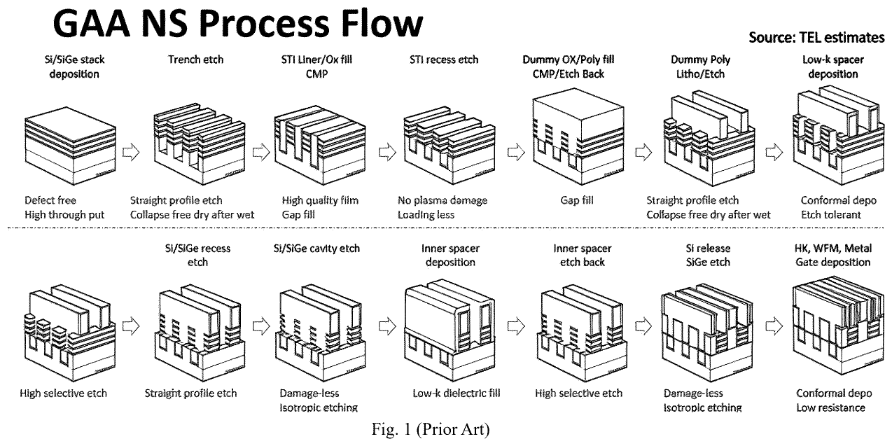

(6) The process of the GAA is shown in FIG. 1, and the overall process is complex.

Therefore, a semiconductor device that can further break through the characteristic size is urgently needed.

To solve the above-described problems, a semiconductor structure and a semiconductor device are provided by the embodiment of the present disclosure. To make the objects, technical schemes, and advantages of the present disclosure clear, the present disclosure is described in further detail in conjunction with accompanying drawings and examples. It should be understood that the specific embodiments described herein are merely used to illustrate the present disclosure, and are not intended to limit the present disclosure.

The terms such as “first”, “second” and the like in the disclosure are used to distinguish similar objects and are not necessarily used to describe a specific sequence or a precedence order. The “connected” and “linked” described in the present disclosure include direct connection and indirect connection (communication) unless otherwise specified. In the descriptions of the disclosure thereof, it is to be understood that orientation or position relationships indicated by terms “up”, “down”, “front”, “rear”, “left”, “right”, “vertical”, “horizontal”, “top”, “bottom”, “inside”, “outside”, “clockwise”, “counterclockwise”, and the like are orientation or position relationships shown in the drawings, are adopted not to indicate or imply that indicated devices or components must be in specific orientations or structured and operated in specific orientations but only to conveniently describe the disclosure and simplify descriptions, and thus should not be understood as limits to the disclosure.

In the present application, unless expressly stipulated and defined otherwise, the first feature is “on” or “under” the second feature may be that the first feature is in direct contact with the second feature, or that the first feature is in indirect contact with the second feature by means of an intermediate medium. Moreover, the first feature is “over”, “above” and “on”, the second feature may be that the first feature is directly above or obliquely above the second feature, or simply means that a level of the first feature is higher than that of the second feature. The first feature is “under”, “below” and “beneath”, the second feature may mean that the first feature is directly below or obliquely below the second feature, or it simply means that the level of the first feature is smaller than that of the second feature.

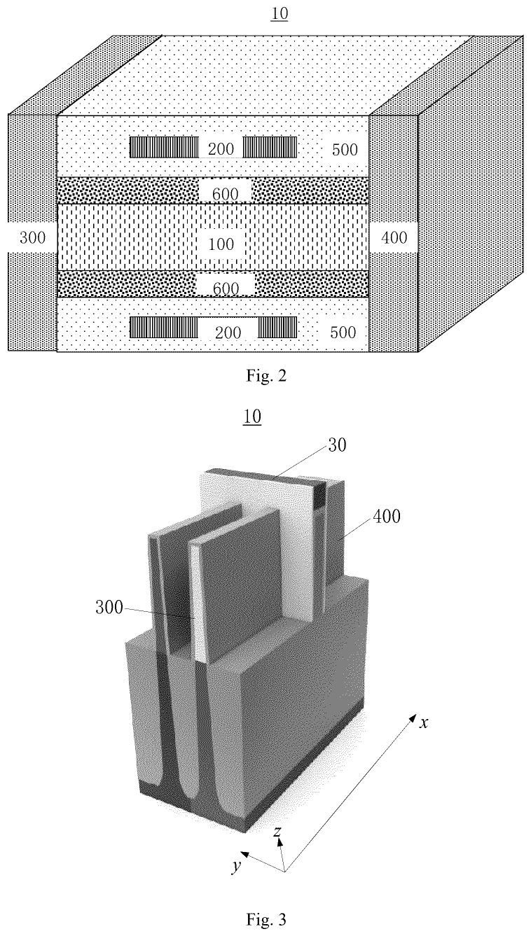

Please refer to FIGS. 2 to 4, the embodiment of the present disclosure provides a semiconductor structure 10 at least comprising: a gate structure 30; a source region 300, and a drain region 400.

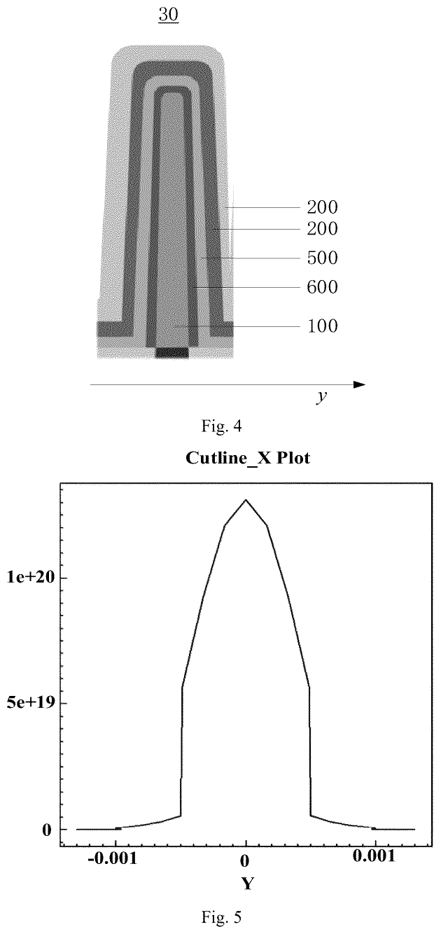

The source region 300 and the drain region 400.are disposed on two sides of the gate structure 30 respectively. Please refer to FIGS. 2 and 3, FIG. 2 is a perspective structure view of the semiconductor structure 10 provided by the embodiment of the present disclosure. FIG. 3 is a simulation structure diagram of the semiconductor structure 10 provided by the embodiment of the present disclosure, including an x-direction along a planar extension and a y-direction along a vertical direction (a depth direction or a height direction). FIG. 4 is a sectional view of the semiconductor structure 10 along the yz direction in FIG. 3.

The gate structure 30 at least comprises: a channel region 100 and a gate region 200 disposed from inside to outside, where the channel region 100 is surrounded inside the inner cavity of the gate region 200, the channel region 100 is attached to the source region 300, the drain region 400, and the gate region 200, and the ion doping types of the drain region 400, the source region 300, and the channel region 100 are the same.

The gate region 200 can be a metal gate and the first ion doping type, the embodiment of the present disclosure is not specifically limited. The gate region 200 can comprise a top gate and a bottom gate, as shown in FIG. 4, the top gate and the bottom gate are both disposed at the surface layer of the channel region 100, and the top gate and the bottom gate can be formed at one time to simplify the process. The source region 300 and the drain 400 can be high-doped regions to improve the movement performance of the conduction electron or hole. The first ion doping type is different from the second ion doping type. That is, the first ion doping type is N-type doping and the second ion doping type is P-type doping, or the first ion doping type is P-type doping and the second ion doping type is N-type doping.

In the first aspect, the drain region 400, source region 300, and the channel region 100 of the embodiment of the present disclosure are all doped with the same type of ions and are homojunction device structure, and no interface effect between the regions. By converting conventional interface conduction to body conduction, the drift velocity of the electron or the drift velocity of the hole is higher and the mobility of the carrier is higher, resulting in a higher drift velocity of the electron or a higher drift velocity of the hole, and further improves the working efficiency and the device reliability of the semiconductor structure 10. The body conduction is the conduction of electrons or holes along the interior of the device layers, differing from the interface conduction of the electric field formed at the interface or the inversion electron layer.

In the second aspect, the drain region 400, the source region 300, and the channel region 100 in the embodiment of the present disclosure are all doped with the same type of ions, the conventional interface conduction is converted into the body conduction, and the channel region 100 being controlled by the gate electrode directly.

With no voltage or 0 V voltage applied to the gate region 200, due to the energy band difference between the gate region 200 and the channel region 100 (the electron affinity of the Si device (the difference between the bottom of the conduction band to the vacuum energy level) is 4.05 eV), the channel region 100 of the device is self-depleted by the affecting of the gate region 200 to form a self-depleted non-inverted semiconductor structure 10. In the case where a voltage is applied to the gate region 200, the current flows from the high doping region of the drain region 400 through the channel region 100 to the source region 300, that is the channel region 100 is turned on. In the case where no voltage is applied to the gate region 200, the channel region 100 in the off state forms a normally-off device structure, consuming less energy than the conventional normally-on device.

In the third aspect, the semiconductor structure 10 provided by the embodiment of the present disclosure is body conduction, and the device has no PN junction structure. The threshold voltage reduction effect caused by the PN junction can be eliminated with no PN junction structure, that is, the characteristic size can be further reduced. Experiments have shown the channel length of the device can meet the requirement of less than 10 nm.

In the fourth aspect, the semiconductor structure 10 provided by the embodiment of the present disclosure is body conduction, the conducting current away from the interface, and no problem of reduced interface mobility. The conducting current away from the interface further reduces tunneling current and gate leakage, and improves the reliability and stability of the device structure.

In the fifth aspect, the semiconductor structure 10 provided by the embodiment of the present disclosure is a non-inverted device, the electrons of the channel region 100 do not flow through the surface inversion layer, thus avoiding leakage from the gate of the device. At the nanoscale, the tunneling current caused by the tunneling effect is the main source of the gate leakage, the thickness of the gate dielectric of the device is limited, and the high-k dielectric has been developed. After adopting the high-k dielectric, the gate dielectric can be thickened without decreasing the control capability of the gate. The semiconductor structure 10 provided by the embodiment of the present disclosure can reduce tunneling current because the current is not on the surface inversion layer, and cannot adopt the high-k dielectric, providing a new technical direction.

Please refer to FIGS. 2 and 4, in an alternative embodiment of the present disclosure, the gate structure region 30 further comprises: a dielectric layer 500, disposed between the gate region 200 and the channel region 100, and attached to the gate region 200, the channel region 100, the drain region 400, and the source region 300, where the gate region 200 is disposed inside different dielectric layer 500.

The dielectric layer 500 can be made of an insulating material such as silicon dioxide, and the gate region 200 is surrounded inside the dielectric layer 500 completely, that is, a thin dielectric is between the gate region 200 and the channel region 100, and similarly, a thin dielectric layer between the bottom gate and the channel. By the structure, an all-surrounded gate structure is formed. That is, the doping of the channel region 100 is circular surrounded by the dielectric layer 500, and only exposes the portions electrically connected to the source region 300 and the drain region 400.

Please refer to FIGS. 2 and 4, in an alternative embodiment of the present disclosure, the gate structure region 30 further comprises a buffer isolation region 600, where: the buffer isolation region 600 is disposed between the channel region 100 and the dielectric layer 500, and attached to the dielectric layer 500, the channel region 100, the drain region 400, and the source region 300.

The gate region 200 and the channel region 100 are isolated by the buffer isolation region 600, and/or, the bottom gate region and the channel region 100 are isolated by the buffer isolation region 600. The buffer isolation region 600 can be a low doping region, that is, the ion doping concentration is less than the ion doping concentration of the drain region 400 and the ion doping concentration of the source region 300. By providing the buffer isolation region 600, the device does not form the surface inversion electron layer at the contact interface between the channel region 100 and the gate region 200, avoiding the performance loss caused by the reduction of the surface mobility, effectively preventing the appearance of the electron tunneling effect, reducing the gate region current, preventing the interface scattering, and improving the reliability and stability of the device.

That is, the buffer isolation region 600 is disposed between each gate region 200 and channel region 100 to not form the surface inversion electron layer at the contact interface between the channel region 100 and the gate region 200, avoiding the performance loss caused by the reduction of the surface mobility, effectively preventing the appearance of the electron tunneling effect, reducing the gate region current, preventing the interface scattering, and improving the reliability and the stability of the device.

That is, the buffer isolation region 600 is of the same ion doping type as the channel region 100, the drain region 400 is of the same ion doping type as the source region 300, and can be grown and formed at the same time to reduce the complexity of the process, avoiding the conventional thermal processes such as the annealing, and improves the yield of the manufacturing of the device structure, as well as the reliability and stability of the performance of the finished device.

In an alternative embodiment of the present disclosure, the ion doping concentration of the buffer isolation region 600 is less than that of the drain region 400 and the source region 300; and/or, the ion doping concentration of the buffer isolation region 600 is one order of magnitude less than that of the channel region 100.

That is, the drain region 400 and the source region 300 are high-ion doped regions, the buffer isolation region 600 is a low-ion doped region, and an ion concentration difference is formed between the two to avoid the electron flow formed by the source region 300 and the drain region 400 scattering from the channel region 100 to the buffer isolation region 600, and further ensure the reliability and the stability of the device structure.

In an alternative embodiment of the present disclosure, the ion doping concentration of the buffer isolation region 600 is no more than 1e17/cm³ as a low-doped region, the thickness of the buffer isolation region 600 is about 0.3 nm to 5 nm, and the buffer isolation region 600 is made of the Si material.

Please refer to FIG. 5, FIG. 5 is a data graph of the device structure when working, illustrating simulation results of the electron concentration of the vertical channel region 100 with a width of 1 nm of the channel region 100 and a thickness of 0.5 nm of the buffer isolation region 600 for example. The horizontal axis represents a position along the vertical direction of the channel in micrometers, where the 0 coordinate point is the center position of the channel in micrometers. The vertical axis represents the electron concentration in/cm³. It can be seen that the electrons of the channel of the device are concentrated inside the channel region 100 in a conducted state, and the electron concentration in the buffer isolation region 600 of the device is reduced by more than one order of magnitude, proving the device is in an internal conduction state.

In an alternative embodiment of the present disclosure, the ion doping concentration of the gate region 200 ranges from 1e16/cm³ to 1e20/cm³; and/or, the ion doping concentration of the channel region 100 ranges from 1e17/cm³ to 5e19/cm³; and/or, the ion doping concentration of the drain region 400 and the ion doping concentration of the source region 300 ranges from 1e18/cm³ to 5e20/cm³.

The device structure by the above concentration parameter range has a better self-depletion effect, better body conduction performance, and fewer other negative effects, further improving the stability and reliability of the device structure.

In an alternative embodiment of the present disclosure, the ion doping concentration of the drain region 400, the ion doping concentration of the source region 300, and the ion doping concentration of the channel region 100 are equal.

That is, the channel region 100, the drain region 400, and the source region 300 are in the same ion doping type and can be grown and formed at the same time to reduce the complexity of the process, avoiding conventional thermal processes such as the annealing, and improving the yield of the manufacturing of the device structure, as well as the reliability and stability of the performance of the finished device.

In an alternative embodiment of the present disclosure, the ion doping concentration of the drain region 400, the ion doping concentration of the source region 300, and the ion doping concentration of the channel region 100 are not less than 1e17/cm³.

That is, the channel region 100, the drain region 400, and the source region 300 are made in the same type of materials, the required ions are injected into the initial materials and no additional ion doping is required during the manufacturing process. The channel region 100, the drain region 400 and the source region 300 can be grown and formed at the same time to reduce the complexity of the process, avoiding conventional thermal processes such as the annealing, and improving the yield of the manufacturing of the device structure, as well as the reliability and stability of the performance of the finished device.

In an alternative embodiment of the present disclosure, the ion doping concentration of the drain region 400, the source region 300, and the channel region 100 are made in one piece. That is, the channel region 100, the drain region 400, and the source region 300 are in the same ion doping type and can be grown and formed at the same time to reduce the complexity of the process, avoiding conventional thermal processes such as the annealing, and improving the yield of the manufacturing of the device structure, as well as the reliability and stability of the performance of the finished device. Moreover, by converting conventional interface conduction to body conduction, no interface effect between the regions at all, the electron drift velocity or the hole drift velocity is higher, and the surface mobility of the carrier is higher, further improving the working efficiency of the semiconductor structure 10 and the device reliability.

In an alternative embodiment of the present disclosure, the semiconductor structure 10 is an N-type device and the gate region 200 is a metal having a metal working function ranging from 4.5 eV to 5.2 eV.

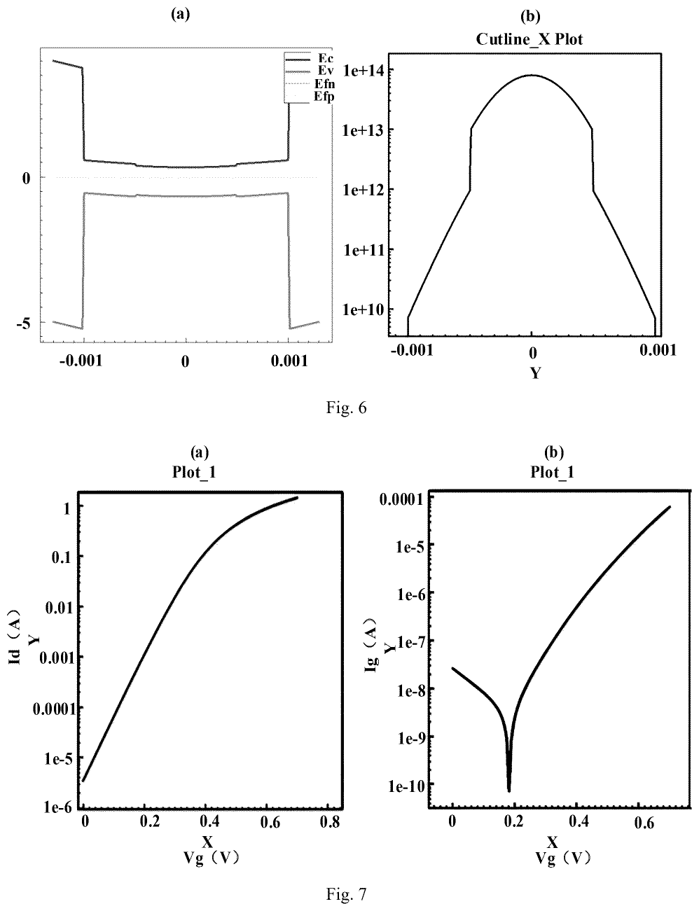

Please refer to FIG. 6, FIG. 6is an energy band diagram and an electron distribution diagram of the buffer isolation region 600 and the channel region 100 of the case where the device is an N-type device in an off state and the metal of gate region 200 has a metal working function ranging from 4.5 eV to 5.2 eV. (a) of FIG. 6 is an energy band diagram, the horizontal axis represents a position along the vertical direction of the channel in a micrometer, where the 0 coordinate point is the center position of the channel and the vertical axis represents the electron concentration in/cm³. (b) of FIG. 6 is an electron distribution diagram of the buffer isolation region 600, the horizontal axis represents a position along the vertical direction of the channel in micrometer, where the 0 coordinate point is the center position of the channel, and the vertical axis represents the electron concentration in/cm³. As shown in FIG. 6, in a case where the metal working function of the gate region 200 ranges from 4.5 eV to 5.2 eV, the Fermi level of the semiconductor layer is located in the middle, the Fermi level distance of the conduction band and the valence band are both closed to 0.5 eV as shown in the diagrams in the silicon material, at the time electrons and holes are both very few, the device is completely shut down, and the performance of the device is excellent.

Please refer to FIG. 7, FIG. 7is simulation result diagrams of the case where the device is an N-type device with a channel thickness of 7 nm and a total gate width of 1 mm. (a) of FIG. 7 is a transfer characteristic curve, the horizontal axis represents the gate current, and the vertical axis represents the drain current. (b) of FIG. 7 is a drain leakage IgVg graph, the horizontal axis represents gate voltage, and the vertical axis represents gate current. As shown in FIG. 7, in a case where the device structure is in the on-off state, the channel current variation is between 6 orders of magnitude, the gate leakage is controlled below 100 uA, and the performance of the device is excellent.

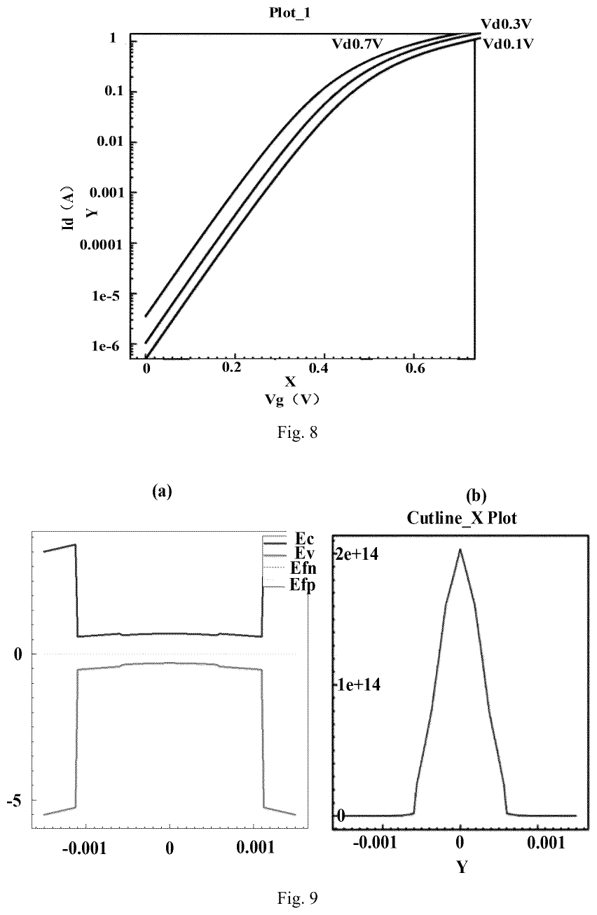

Please refer to FIG. 8, FIG. 8 is an IdVg curve graph for different Vd of the N-type device. As shown in FIG. 8, the difference in the current of the device for different drain voltages is small, and the drain-induced barrier lowering (DIBL) characteristic is better.

In an alternative embodiment of the present disclosure, the semiconductor structure 10 is a P-type device and the gate region 200 is a metal having a metal working function ranging from 4.0 eV to 4.5 eV.

Please refer to FIG. 9, FIG. 9is an energy band diagram and a hole distribution diagram of the buffer isolation region 600 and the channel region 100 of the case where the device is a P-type device in an off state and the metal of gate region 200 has a metal working function ranging from 4.0 eV to 4.5 eV (a) of FIG. 9 is an energy band diagram, the horizontal axis represents a position along the vertical direction of the channel in micrometer, where the 0 coordinate point is the center position of the channel and the vertical axis represents the electron concentration in/cm³. (b) of FIG. 9 is a hole distribution diagram of the buffer isolation region 600, the horizontal axis represents a position along the vertical direction of the channel in micrometer, where the 0 coordinate point is the center position of the channel, and the vertical axis represents the hole concentration. As shown in FIG. 9, in a case where the metal working function of the gate region 200 ranges from 4.0 eV to 4.5 eV and in an off state, the Fermi level is located in the middle of the band gap, the holes are very few, the device is completely turned off, and the performance of the device is excellent.

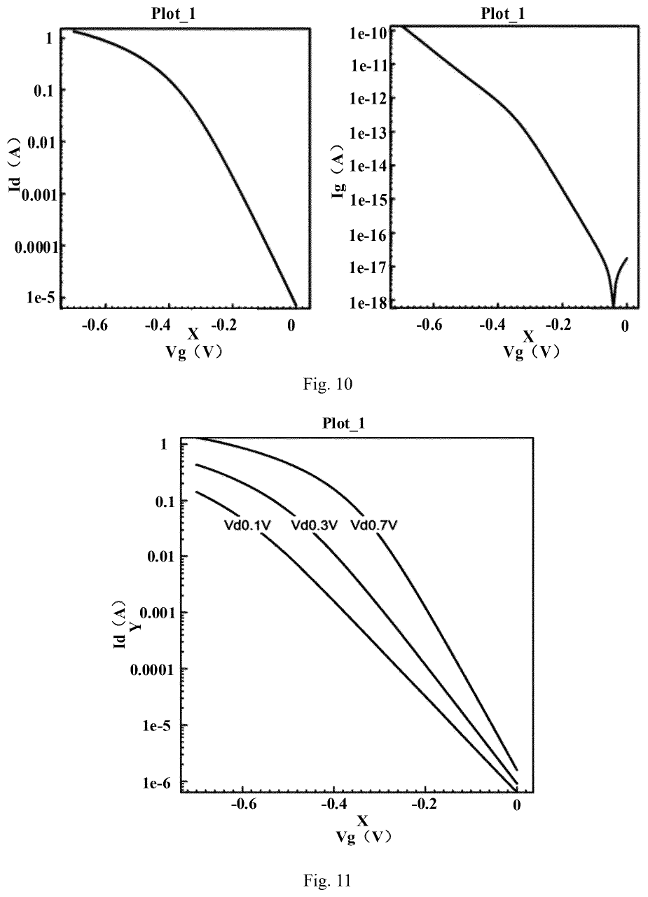

Please refer to FIG. 10, FIG. 10 is simulation result diagrams of the case where the device is a P-type device with a channel thickness of 7 nm and a total gate width of 1 mm. (a) of FIG. 10 is a transfer characteristic curve, the horizontal axis represents the gate current, and the vertical axis represents the drain current. (b) of FIG. 10 is a drain leakage IgVg graph, the horizontal axis represents gate voltage, and the vertical axis represents gate current. As shown in FIG. 10, in a case where the device structure is in the on-off state, the channel current variation is between 5 orders of magnitude, the gate leakage is controlled below 100 uA, and the performance of the device is excellent.

Please refer to FIG. 11, FIG. 11 is an IdVg curve graph for different Vd of the P-type device. As shown in FIG. 11, the difference in the current of the device for different drain voltages is small, and the drain induced barrier lowering (DIBL) characteristic is better.

In an alternative embodiment of the present disclosure, the semiconductor structure 10 can be a FinFET device or a GAA device.

Please referring the beneficial effects of the semiconductor structure 10 as described above, the embodiment of the present disclosure provides a semiconductor device 20 with body conduction, non-inversion layer, small tunneling effect, small gate leakage, low power consumption, higher electron drift velocity or hole drift velocity, higher mobility efficiency of the carrier, small characteristic size and breakthrough the limiting of the device size.

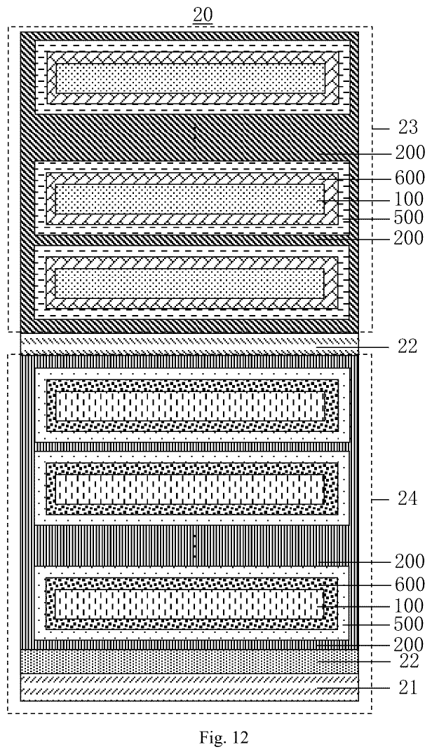

Please refer to FIG. 12, the embodiment of the present disclosure provides a semiconductor structure 20, and the semiconductor structure 20 comprises:
any one of the semiconductor structures 10 as described above.

Please referring the beneficial effects of the semiconductor structure 10 as described above, the embodiment of the present disclosure provides a semiconductor structure 20 with body conduction, non-inversion layer, small tunneling effect, small gate leakage, low power consumption, higher electron drift velocity or hole drift velocity, higher mobility efficiency of the carrier, small characteristic size and breakthrough the limiting of the device size.

As shown in FIG. 12, in an alternative embodiment of the present disclosure, the number of the semiconductor structures 10 is a plurality; the conduction type of the plurality of the semiconductor structures 10 is not identical, and the plurality of semiconductor structures 10 is insulated from each other by insulating layers 22. It is to be explained that the plurality of semiconductor structure 10 can be stacked or arranged along any direction in the actual produce, FIG. 12 does not constitute a specific limitation of the semiconductor device 20 and the arrangement of the semiconductor structure 10.

That is, both N-type semiconductor device 20 and P-type semiconductor device 20 can be realized in the same device, and for example, a complementary FET can be made by 3D integration to form a logic unit realizing logic function. In the first aspect, the N-type semiconductor device 20 and the P-type semiconductor device are integrated in the same three-dimensional structure in the embodiment of the present disclosure, improving the integration level and reducing the area; In the second aspect, the delay caused by the connection wires can be reduced and the performance of the device can be improved. As shown in FIG. 12, the devices are divided into two types as example, the first conduction type device is between the bottom insulating layer 22 on the substrate layer 21 and the middle insulating layer 22, and the second conduction type device is on the middle insulating layer 22. The two types of devices are an NFET and a PFET in complementary, the number of the NFET and the PFET can be a plurality, and the metal layers of the NFET and the PFET have different metal working functions.

Please referring the beneficial effects of the semiconductor structure 10 as described above, the embodiment of the present disclosure provides a complementary-type FET device or GAA device with body conduction, non-inversion layer, small tunneling effect, small gate leakage, low power consumption, higher electron drift velocity or hole drift velocity, higher mobility efficiency of the carrier, small characteristic size and breakthrough the limiting of the device size.

In an alternative embodiment of the present disclosure, the semiconductor device 20 as described above comprises: a first semiconductor substrate 23 and a second semiconductor structure are stacked along the vertical direction on the surface of the substrate 21, the first semiconductor structure comprises a plurality of the first conduction type semiconductor structures, the second semiconductor structure comprises a plurality of the second conduction type semiconductor structures, and the first conduction type is different from the second conduction type. For example, the first conduction type is an N-type conduction and the second conduction type is a P-type conduction, or the first conduction type is a P-type conduction and the second conduction type is an N-type conduction.

As described above, the embodiment of the present disclosure provides a P-type and N-type complementary-type semiconductor device with body conduction, non-inversion layer, small tunneling effect, small gate leakage, low power consumption, higher electron drift velocity or hole drift velocity, higher mobility efficiency of the carrier, small characteristic size and breakthrough the limiting of the device size.

In an alternative embodiment of the present disclosure, the semiconductor device 20 as described above further comprises: an insulating layer 22, disposed between the first semiconductor structure 23 and the second semiconductor structure 24, and through the gate region 200. The first semiconductor structure 23 and the second semiconductor structure 24 are isolated by the insulating layer 22, ensuring the relative independence of the first semiconductor structure 23 and the second semiconductor structure 24, avoiding mutual interference, and improving the stability and reliability of the device.

It is to be understood that, although the steps in the flowcharts are sequentially shown according to an indication of arrows, the steps are not necessarily sequentially performed according to a sequence indicated by the arrows. Unless otherwise explicitly stated in this specification, these steps are not necessarily performed in a strictly limited order, and the steps may be performed in other orders. Besides, at least some steps in the flowchart may include a plurality of sub-steps or a plurality of stages, the sub-steps or stages are not necessarily performed at the same moment and may be performed at different moments, the sub-steps or stages are not necessarily sequentially performed, and the sub-steps or stages and at least some of other steps or sub-steps or stages of other steps may be performed in turn or alternately.

The technical features of the embodiments described above may be combined in any way. For brevity of description, possible combinations of the technical features in the foregoing embodiments are not exhausted, which, however, are to be considered as falling within the scope of this specification as long as there is no contradiction in the combinations of these technical features.

The foregoing embodiments show only several implementations of the present disclosure and are described in detail, which, however, are not to be construed as a limitation to the patent scope of the present disclosure. It should be noted that a person of ordinary skill in the art may further make several variations and improvements without departing from the ideas of the present disclosure, and such variations and improvements fall within the protection scope of the present disclosure. Therefore, the protection scope of this patent application is subject to the protection scope of the appended claims.

What is claimed is:

1. A semiconductor structure, comprising:
a gate structure region; and
a source region and a drain region, disposed on two sides of the gate structure respectively;
wherein the gate structure region comprises:
a channel region and a gate region disposed from inside to outside, wherein the channel region is surrounded inside an inner cavity of the gate region and attached to the source region, the drain region, and the gate region, and an ion doping type of the drain region, an ion doping type of the source region and an ion doping type of the channel region are same.

2. The semiconductor structure according to claim 1, wherein the gate structure region further comprises:
a dielectric layer, disposed between the gate region and the channel region and attached to the gate region, the channel region, the drain region, and the source region.

3. The semiconductor structure according to claim 2, wherein the gate structure region further comprises:
a buffer isolation region, disposed between the channel region and the dielectric layer, and attached to the dielectric layer, the channel region, the drain region, and the source region.

4. The semiconductor structure according to claim 3, wherein an ion doping concentration of the buffer isolation region is not more than 1e17/cm³.

5. The semiconductor structure according to claim 3, wherein an ion doping concentration of the buffer isolation region is less than an ion doping concentration of the drain region and an ion doping concentration of the source region.

6. The semiconductor structure according to claim 3, wherein a thickness of the buffer isolation region ranges from 0.3 nm to 5 nm.

7. The semiconductor structure according to claim 1, wherein an ion doping concentration of the gate region ranges from 1e16/cm³ to 1e20/cm³.

8. The semiconductor structure according to claim 1, wherein an ion doping concentration of the drain region, an ion doping concentration of the source region, and an ion doping concentration of the channel region are equal.

9. The semiconductor structure according to claim 8, wherein the ion doping concentration of the drain region, the ion doping concentration of the source region, and the ion doping concentration of the channel region are not less than 1e17/cm³.

10. The semiconductor structure according to claim 1, wherein the drain region, the source region, and the channel region are made integrally.

11. The semiconductor structure according to claim 1, wherein the semiconductor structure is an N-type device, and the gate region is a metal having a metal working function ranging from 4.5 eV to 5.2 eV.

12. The semiconductor structure according to claim 1, wherein the semiconductor structure is selected from at least one of a fin field-effect transistor (FinFET) device or a gate-all-around transistor (GAA) device.

13. The semiconductor structure according to claim 3, wherein an ion doping concentration of the buffer isolation region is one order of magnitude less than an ion doping concentration of the channel region.

14. The semiconductor structure according to claim 1, wherein an ion doping concentration of the channel region ranges from 1e17/cm³ to 5e19/cm³.

15. The semiconductor structure according to claim 1, wherein an ion doping concentration of the drain region and an ion doping concentration of the source region ranges from 1e18/cm³ to 5e20/cm³.

16. The semiconductor structure according to claim 1, wherein the semiconductor structure is a P-type device and the gate region is a metal having a metal working function ranging from 4.0 eV to 4.5 eV.

17. A semiconductor device, comprising:
a substrate layer; and
a first semiconductor substrate and a second semiconductor structure, stacked along a vertical direction on a surface of the substrate layer, wherein the first semiconductor structure comprises a plurality of semiconductor structures of a first conduction type, the second semiconductor structure comprises a plurality of semiconductor structures of a second conduction type;
wherein each of the plurality of semiconductor structure comprises:
a gate structure region; and
a source region and a drain region, disposed on two sides of the gate structure respectively;
wherein the gate structure region comprises:
a channel region and a gate region, disposed from inside to outside, wherein the channel region is surrounded inside an inner cavity of the gate region and attached to the source region, the drain region, and the gate region, and an ion doping type of the drain region, an ion doping type of the source region and an ion doping type of the channel region are same.

18. The semiconductor device according to claim 17, wherein conduction types of the plurality of the semiconductor structures are not identical.

19. The semiconductor device according to claim 17, wherein
the first conduction type is different from the second conduction type.

20. The semiconductor device according to claim 17, further comprising:
an insulating layer, disposed between the first semiconductor structure and the second semiconductor structure, and through the gate region of each of the plurality of the semiconductor structures.
